(19) United States
(12) Patent Application Publication
(10) Pub. No.: US 2025/0078902 A1
(43) Pub. Date: Mar. 6, 2025

(54) VOLTAGE-THRESHOLD VIOLATION DETECTION CIRCUITS IN MEMORY DEVICES AND SYSTEMS

(71) Applicant: Micron Technology, Inc., Boise, ID (US)

(72) Inventor: Sangjin Byeon, Boise, ID (US)

(21) Appl. No.: 18/789,682

(22) Filed: Jul. 31, 2024

Related U.S. Application Data
(60) Provisional application No. 63/535,024, filed on Aug. 28, 2023.

(51) Int. Cl. G11C 11/4074; G11C 5/14; G11C 11/4076

(52) U.S. Cl. CPC G11C 11/4074; G11C 5/147; G11C 11/4076

(57) ABSTRACT

A method to attenuate excessive supply voltage fluctuations in a memory system comprising a memory controller and a memory device configured to store and retrieve data is provided. The method includes detecting a potential supply voltage fluctuation at a voltage-threshold violation detection circuit in the memory controller, wherein the potential supply voltage fluctuation corresponds to an inrushing current from an initialization state or a surge of current from a switch to a busy state after staying in a long-term idle state. In response to detecting the potential supply voltage fluctuation, the method includes generating a control signal from the voltage-threshold violation detection circuit. The method includes transmitting the control signal from the memory controller to the memory device. The method includes decoding the control signal in the memory device. The method includes attenuating the potential supply voltage fluctuation to prepare for memory access.

### CROSS-REFERENCE TO RELATED APPLICATION(S)

The present application claims priority to U.S. Provisional Patent Application No. 63/535,024, filed Aug. 28, 2023, the disclosure of which is incorporated herein by reference in its entirety.

### TECHNICAL FIELD

The present disclosure relates to memory devices, particularly to voltage-threshold violation detection circuits in memory devices and systems.

### BACKGROUND

Memory devices are widely used to store information related to various electronic devices such as computers, wireless communication devices, cameras, digital displays, and the like. Memory devices may be volatile or non-volatile and can be of various types, such as magnetic hard disks, random access memory (RAM), read-only memory (ROM), dynamic RAM (DRAM), synchronous dynamic RAM (SDRAM), and others. Information is stored in various types of RAM by charging a memory cell to have different states. Improving RAM memory devices, generally, can include increasing memory cell density, increasing read/write speeds, or otherwise reducing operational latency, increasing reliability, increasing data retention, reducing power consumption, or reducing manufacturing costs, among other metrics.

### BRIEF DESCRIPTION OF THE DRAWINGS

FIG. 1 illustrates a diagram illustrating excessive supply voltage fluctuations occurring in a memory device.

FIG. 2 illustrates the effects of attenuating excessive supply voltage fluctuations, in accordance with embodiments of the present technology.

FIG. 3 illustrates a voltage-threshold violation detection circuit, in accordance with embodiments of the present technology.

FIG. 4 illustrates an inrushing current detector, in accordance with embodiments of the present technology.

FIG. 5A illustrates a surging current detector as part of a memory controller, in accordance with embodiments of the present technology.

FIGS. 5B and 5C illustrate a surging current detector as part of a memory device, in accordance with embodiments of the present technology.

FIG. 6 illustrates a system configured to attenuate supply voltage fluctuations, in accordance with embodiments of the present technology.

FIG. 7 illustrates a memory system configured to attenuate supply voltage fluctuations, in accordance with embodiments of the present technology.

FIG. 8 illustrates a flowchart illustrating a method of attenuating excessive supply voltage fluctuations in a memory subsystem comprising a memory controller and a memory device configured to store and retrieve data.

FIG. 9 illustrates a block diagram of a system that includes a semiconductor memory device configured in accordance with an embodiment of the present technology.

### DETAILED DESCRIPTION

Semiconductor memory can be structured in memory subsystems that include a memory device and a memory controller. When the memory controller accesses the memory device (e.g., in response to a cache miss in a processing unit coupled to the memory controller), a voltage supplied by a Power Management Integrated Circuit (PMIC) to the memory device may be adjusted to reach a target voltage (e.g., a voltage sufficient to respond to the memory device access by the memory controller). The memory device may respond to the change in the supply voltage over a period of time, where the duration of the time to respond and/or delay to respond may be based on characteristics of the system's Power Delivery Network (PDN), as well as an amount of current used in the memory device. However, these fluctuations in the supply voltage, and the typical delay in responding to supply voltage changes (e.g., when the memory device is accessed), can lead to defects in the operation of the internal circuit within the interface of the memory device. Defects may occur within the memory device, for example, when the supply voltage fluctuates beyond voltage ranges allowed for normal operations. As described herein, the voltage fluctuations can be more excessive when the memory device is accessed in certain situations, such as when the memory device is powered on or after long periods of inactivity.

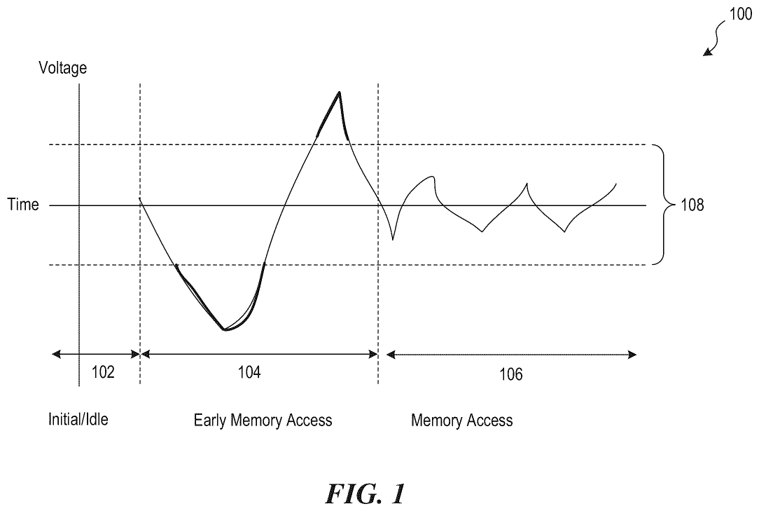

For example, FIG. 1 illustrates a diagram 100 illustrating excessive supply voltage fluctuations occurring in a memory device. These fluctuations can occur over distinct periods of time. As illustrated, the memory device may begin in an Initial/Idle period 102. The Initial/Idle period 102 may correspond to a period during which the memory device receives no system power (e.g., has not yet been powered-up) and/or receives minimal power (e.g., the memory device receives some system power, but not enough power to be functional and the memory device has yet to be initialized). The Initial/Idle period 102 may additionally correspond to a period during which the memory device is idle (e.g., initialized but not being accessed). Subsequently, the memory device may be accessed (e.g., it receives a request/command from a memory controller) and/or receives signaling and/or power (e.g., a Power Up or Reset signal) to begin initialization, during which it enters an Early Memory Access period 104. During the Early Memory Access period 104, the memory device is supplied with current. In the Early Memory Access period 104, the voltage supplied to the memory device fluctuates with a large amplitude. For example, as illustrated in FIG. 1, the voltage fluctuations can exceed a min-max threshold value 108 of the memory device, which may cause defects or other errors. The large amplitude may be caused by a sudden change in current when first initializing the memory device (e.g., an inrushing current triggered by a change in a Power Up signal or Reset signal) or a sudden change in current when first accessing the memory device after a long period of inactivity (e.g., a surging current).

As illustrated in FIG. 1, the supply voltage may fluctuate greatly, but at a low frequency, during the Early Memory Access period 104. The fluctuation continues until the memory device consumes a relatively constant amount of current or until an equilibrium is reached between a supply of current and its consumption. Once this equilibrium has been reached, during which the supply voltage may continue to fluctuate but no longer exceeds min-max threshold value 108 of the memory device, the memory device may be said to have entered a Stable Memory Access period 106.

It will be appreciated that the amplitude of voltage fluctuations (e.g., illustrated during the Early Memory Access period 104 and/or Stable Memory Access period 106) may depend on (e.g., be mitigated by) the presence and/or size of a decoupling capacitor. However, there can be various challenges with using an ideally sized decoupling capacitator in a memory subsystem, sufficient to address the issues discussed above, due to problems with area and cost that such a large capacitor may incur. Moreover, even if the response speed of the PMIC or Voltage Regulators (VRs) during normal operation is as fast as several microseconds after initialization and/or in the transition from idle to busy state, both the memory controller and the memory device consume a large amount of current, which typically exceeds the charge stored in the decoupling capacitor to cover it. In such an instance, the min-max threshold value 108 of the potential at which the memory device can operate normally may be exceeded. Under this condition, defects occur in the operation of the internal circuit within the interface of the memory.

To address these and other shortcomings, methods, systems, and apparatuses for memory systems and/or memory devices are disclosed, which detect instances in which a supply voltage of a memory device may exceed allowed voltage thresholds of the memory device (e.g., when the memory device is subject to inrushing current and/or surging current). In response to detecting the likelihood of a voltage supply that may exceed allowable thresholds, the methods, systems, and apparatuses may utilize various techniques, described below, to reduce the amplitude of supply voltage fluctuations (e.g., attenuate the supply voltage). As described herein, in various embodiments, the memory devices and/or other components of the memory system (e.g., the memory controller) may include voltage-threshold violation detection circuits.

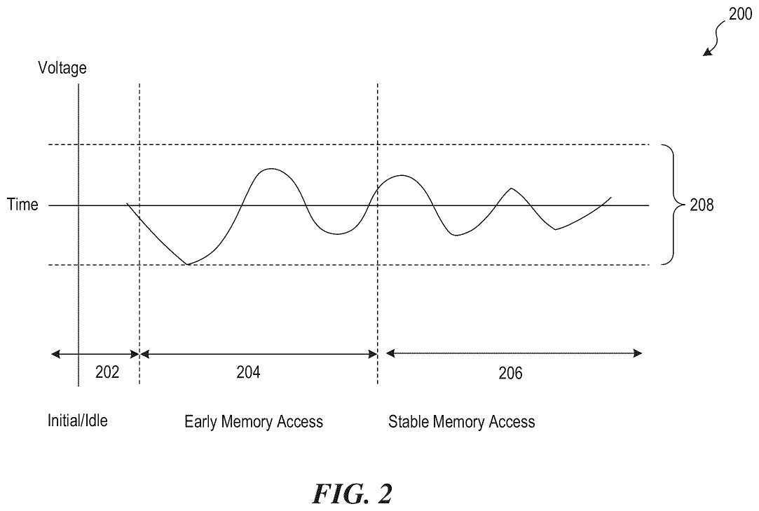

FIG. 2 illustrates the effects 200 of attenuating excessive supply voltage fluctuations, in accordance with embodiments of the present technology. As described herein, the attenuation of excessive supply voltage fluctuations can be facilitated by the disclosed voltage-threshold violation detection circuit, which may be part of a memory device and/or a memory controller coupled to the memory device. As described herein, the voltage-threshold violation detection circuit (e.g., in a memory controller and/or memory device) detects circumstances in which it is likely that a supply voltage of a memory device fluctuates to levels exceeding allowed voltage thresholds of the memory device. For example, the excessive supply voltage fluctuation may be associated with an inrush of current caused by a transition from an Initial/Idle period 202. As described herein, the voltage-threshold violation detection circuit can detect a likelihood of inrush current based on one or more signals received from a host device (e.g., a Power Up signal and/or a Reset signal), which indicate that the memory device will be powered-on and/or initialized, thereby exiting the Initial/Idle period 202. As a further example, the excessive supply voltage fluctuation may be associated with a surge of current caused by a transition from an Initial/Idle period 202 (e.g., when the memory device enters a busy state caused by a memory access). As described herein, the voltage-threshold violation detection circuit can detect a likelihood of surge current when it determines that the memory device will be active after a sufficiently long period of inactivity (e.g., after a number of clock cycles, exceeding a threshold, in the Initial/Idle period 202). When the voltage-threshold violation detection circuit detects a likelihood of inrush current and/or surge current, it can signal one or more components of the memory system (e.g., the memory controller, the memory device, PMICs, VRs, etc.) to employ one or more mitigation techniques.

In response to detecting a likely excessive supply voltage fluctuation, the voltage-threshold violation detection circuit generates an indication notifying the memory device of the expected excessive supply voltage fluctuation. As described herein, the notification can be in the form of a command to be decoded by the memory device and/or the memory controller, part of the payload of a packet of control information, one or more individual signals, and/or other forms of conveying control information to the memory device and/or the memory controller (collectively, a “control signal”). It will be appreciated that, in embodiments, the control signal asserts (e.g., indicates a likelihood of an excessive voltage fluctuation) prior to an actual voltage fluctuation occurring. Further, in some embodiments, the control signal may assert without a subsequent voltage fluctuation occurring. In said embodiments, however, the control signal may produce none or acceptable deleterious effects on the performance of the memory device or memory system as a whole. That is, in some embodiments the control signal may assert, based on a likelihood of an excessive voltage fluctuation occurring, to preempt any possibility of memory operation defects from occurring, even though no voltage fluctuation may subsequently occur. The voltage-threshold violation detection circuit may detect the likelihood of excessive voltage fluctuations, and assert the control signal, at the transition between the Initial/Idle period 202 and an Early Memory Access period 204.

In some embodiments, the control signal is a command to be decoded by the memory device and/or the memory controller. For example, in embodiments in which the voltage-threshold violation detection circuit is part of a memory controller, the memory controller can transmit the control signal command to the memory device over a memory channel (for example, a command bus, an address bus, and/or a command/address bus). As a further example, in embodiments in which the voltage-threshold violation detection circuit is part of the memory device, the voltage-threshold violation detection circuit can generate a command to be decoded by other components of the memory device (e.g., a command decoder). In some embodiments, the command is a Dummy Command. In some embodiments, the command is a Mode Register Set (MRS) command.

In some embodiments in which the voltage-threshold violation detection circuit generates a MRS command, the command can be used to write data (e.g., a 0 or 1) to a designated bit in a register that indicates the detection of likely excessive voltage fluctuations. For example, the MRS command can write an unused bit in a register (e.g., bit designated as Reserved for Future Use) to indicate the detection. As a further example, the MRS command write to a new bit (e.g., by extending MRS registers).

In some embodiments in which the voltage-threshold violation detection circuit generates a Dummy Command, the command can be a new command added to a Command Truth Table that specified one or more command used by components of the memory system (e.g., memory device, memory controller, etc.). In such embodiments, the memory device and the memory controller can distinguish the Dummy Command from a prior command to prepare for a next operation. In some embodiments, the voltage-threshold violation detection circuit generates an existing command as the Dummy Command. For example, the memory controller can use an Active-Precharge command combination as the Dummy Command by issuing it through a CA bus to the memory device, where it transmits a ready signal that informs the memory device of the start of the subsequent access. Through this, the memory device can prepare for the subsequent operation of the memory controller.

In some embodiments in which the voltage-threshold violation detection circuit is part of a memory controller, the control signal is transmitted to the memory device through the memory channel (e.g., a command/address bus, as described above, and/or other components of the memory channel) or through a side-band channel independent of the memory channel. For example, the control signal can be transmitted over an I2C bus, I3C bus, or similar bus through which the memory controller and memory device are coupled.

Based on the control signal, the memory device and/or the memory controller can prepare for the expected memory access before the memory access occurs. That is, the memory device and/or the memory controller can attenuate the supply voltage fluctuation in an Early Memory Access period 204, thereby reducing an amplitude of the voltage in order to keep it within a min-max threshold value 208. By doing so, the memory device and/or the memory controller may avoid memory operation defects. As described herein, the memory device and/or the memory controller can respond to the control signal in different ways to attenuate the supply voltage fluctuations. The described system may use, in different embodiments, the different responses to attenuate the supply voltage fluctuations alone and/or in combination.

In some embodiments, the control signal causes the memory device to consume an initial amount of current. For example, the memory device and/or the memory controller may operate a current consuming circuit in response to the control signal. The memory device and/or controller may include one or more circuits that can be used to control current consumption and/or supply, and that can be used to consume an initial amount of current in response to the control signal. For example, the memory device may include a comparator that compares a reference voltage with an internal voltage generated by an LDO (Lower Drop Down) using an external power supply. As a further example, in some embodiments there is a PMOS (P-Channel Metal-Oxide-Semiconductor) driver (for pull up) and/or an NMOS (N-Channel Metal-Oxide-Semiconductor) driver (for pull down), driven by an output of the comparator. In other embodiments, other approaches may be used to change the performance of a power supply and/or control an amount or shape of the power supply.

In some embodiments, the current consuming circuit may be operated based on the control signal (e.g., at the end of the Initial/Idle period 202) but prior to memory access (e.g., before the Early Memory Access period 204). For example, the current consuming circuit may be operated during an additional period, not illustrated in FIG. 2, at the transition between the Initial/Idle period 202 and Early Memory Access period 204. It will be appreciated that, in such embodiments, the initial amount of consumed current can cause the supply voltage fluctuation to occur prior to the memory device actually being accessed (e.g., prior to the Early Memory Access period 204). In this way, an excessive supply voltage fluctuation can occur, and lapse, before any memory operation defects can occur.

In some embodiments, the control signal causes components of the memory subsystem, such as one or more PMICs, VRs, and/or PDNs, to be adjusted. For example, the control signal can cause a change in the response speed or driving ability of a VR. In such embodiments, VR adjustment includes temporarily increasing the response speed and/or driving ability of the VR. In some embodiments, the adjusted VR is part of and/or associated with the memory device.

Additionally, the control signal can cause adjusting a voltage training of the memory system to minimize the effect of supply voltage fluctuations. In this case, adjusting the voltage training can include increasing a number of clock cycles used to determine an average demand for current in the memory device. In this way, supply voltage fluctuations can be mitigated by determining values that are less sensitive to short-term fluctuations, e.g., supply voltage fluctuations occurring in the Early Memory Access period 204, for training cycles and timing of the interface circuit. For example, when switching from the Initial/Idle period 202 to another state (e.g., a busy state), the training cycle can be increased, and the average value of multiple training results can be used. Such values can be applied to the current and frequency characteristics of the memory device and/or the memory controller or to a training cycle algorithm. Once voltage equilibrium has been reached, the memory system and/or the memory device therein enters a Stable Memory Access period 206.

In some embodiments, the memory device includes a cap (e.g., a miller cap, load cap, or decoupling cap) that improves (e.g., decrease) a response speed of the comparator by changing an amount of current supplied to or consumed by an externally supplied power supply. In some embodiments, the cap improves a response speed of the internal power supply device by changing an amount of current supplied or drained to the internal power.

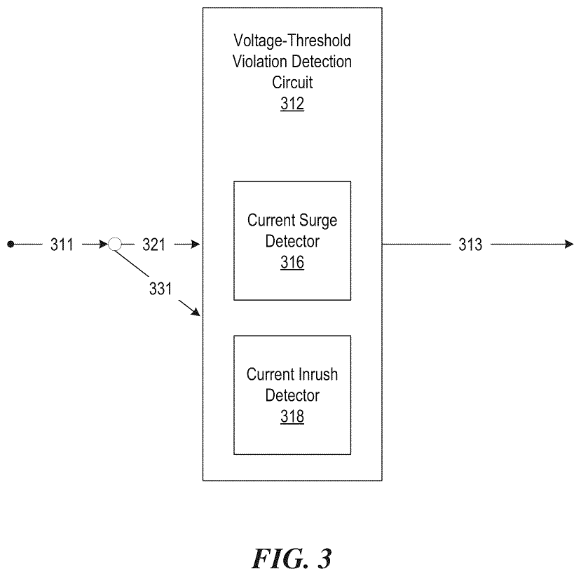

FIG. 3 illustrates a voltage-threshold violation detection circuit 312, in accordance with embodiments of the present technology. The voltage-threshold violation detection circuit 312 detects circumstances in which it is likely that a supply voltage of a memory device will fluctuate to levels exceeding an allowed voltage threshold for the memory device. In some embodiments, the voltage-threshold violation detection circuit 312 receives as inputs one or more indicators characterizing potential expected changes in the voltage supply of a memory device, such as a memory access indicator 321 and/or a power up indicator 331 (collectively, voltage fluctuation indicators 311). As described herein, the voltage-threshold violation detection circuit 312 can detect possible supply voltage fluctuations (e.g., caused by an inrush of current or a surge of current) based on the voltage fluctuation indicators 311.

The voltage-threshold violation detection circuit 312 can detect a likelihood of the power up indicator 331 based on one or more signals received from a host device (e.g., a Power Up signal and/or a Reset signal), indicating the memory device will be initialized or reset. In the case of the power up indicator 331, the initialization state can be detected by the voltage-threshold violation detection circuit 312 or by a current inrush detector 318 belonging to the voltage-threshold violation detection circuit 312. The current inrush detector 318 can detect the power up indicator 331 by receiving a Power Up signal, or a Reset signal, sent by an external processor to the memory controller and/or to the memory device.

In some embodiments, the voltage-threshold violation detection circuit 312 can detect a likelihood of the memory access indicator 321 based on a determination that the memory device will be active after a sufficiently long period of inactivity (e.g., after a number of clock cycles exceeding a threshold). The memory access indicator 321 can be detected by the voltage-threshold violation detection circuit 312 through a current surge detector 316. The current surge detector 316 can include a Clock Generator and an Initial Idle Controller. The current surge detector 316 measures idle time following a most recent surge in current to the memory device. The memory access indicator 321 can be from a PMIC. Measuring can occur by counting a number of clock cycles and comparing the number to a threshold. Once the number of clock cycles passes a threshold, the current surge detector 316 alerts the voltage-threshold violation detection circuit 312 to the likelihood of a potential supply voltage fluctuation creating poor Power Integrity (PI) in the memory device.

When the voltage-threshold violation detection circuit detects the likelihood of the power up indicator 331 or the memory access indicator 321 based on voltage fluctuation indicators 311, it can signal one or more components of the memory system (e.g., the memory controller, the memory device, PMICs, VRs, etc.) to employ one or more mitigation techniques. In response to detecting a likely excessive supply voltage fluctuation, the voltage-threshold violation detection circuit can generate an indication notifying the memory device. The indication can be in the form of a command to be decoded by the memory device and/or the memory controller, part of the payload of a packet of control information, one or more individual signals, and/or other forms of conveying control information to the memory device and/or the memory controller (collectively, a control signal 313). In some embodiments, the control signal 313 is a Dummy Command. In some embodiments, the control signal 313 is an MRS command.

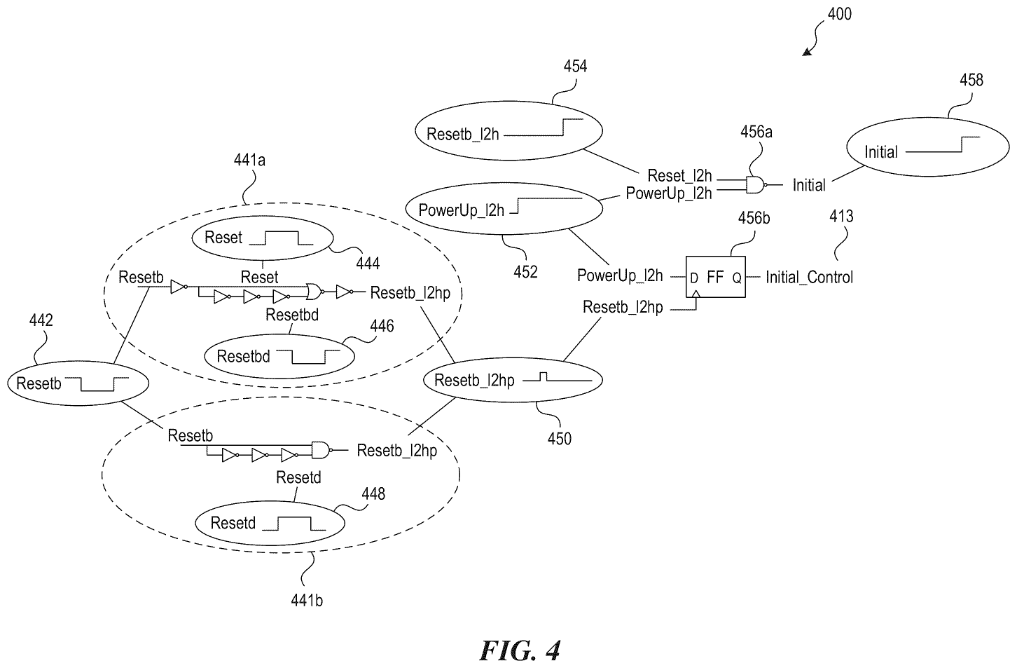

FIG. 4 illustrates an inrushing current detector 400, in accordance with embodiments of the present technology. As described herein, the inrushing current detector 400 (which may be part of a memory device and/or memory controller) can detect the likelihood of an inrushing current based on, for example, a Power Up and/or Reset condition. As illustrated in FIG. 4, the inrushing current detector 400 receives a Resetb signal 442, based on which it can generate a Resetb_l2 hp signal 450. As illustrated in FIG. 4, the Resetb_l2 hp signal 450 may pulse from low to high (e.g., from 0 to 1) following the Resetb signal 442 going low (e.g., changing to 0). In some embodiments, the inrushing current detector 400 generates the Resetb_l2 hp signal 450 using a first logic path 441a. As illustrated in FIG. 4, the first logic path 441a can include a plurality of logic gates (e.g., inverters, NAND gates, and/or NOR gates). The first logic path 441a can additionally generate a Reset signal 444 and a Resetbd signal 446. In some embodiments, the inrushing current detector 400 generates the Resetb_l2 hp signal 450 using a second logic path 441b. As illustrated in FIG. 4, the second logic path 441b can include a plurality of logic gates (e.g., inverters, NAND gates, and/or NOR gates). The second logic path 441b can additionally generate a Resetd signal 448. As illustrated in FIG. 4, the Resetb_l2 hp signal 450 (generated from the first logic path 441a or the second logic path 441b) can control a flip-flop (FF) circuit 456b. For example, the Resetb_l2 hp signal 450 can control the reset signal of FF circuit 456b. The inrushing current detector 400 additionally receives a Resetb_l2h signal 454, and a PowerUp_l2h signal 452. The PowerUp_l2h signal 452 may couple to the D-input of the FF circuit 456b, which output an Initial_Control signal 413. The inrushing current detector 400 can additionally include a NAND gate 456a, which generates an Initial signal 458 based on the Resetb_l2h signal 454 and the PowerUp_l2h signal 452.

Although created by different logic paths, 441a and 441b, the Resetb_l2 hp signal 450 may be used for the same purpose in either path. Additionally, in other embodiments, the Resetb_l2 hp signal 450 and the Resetb signal 442 can be generated in other ways. Both the Initial signal 458 and the Initial_Control signal 413 can be generated from the PowerUp (=PowerUp_l2h) & Resetb (Resetb_l2h). The Resetb signal 442 and the PowerUp_l2h signal 452 can have different generation methods and perform the same function (e.g., detecting that an inrush current may occur).

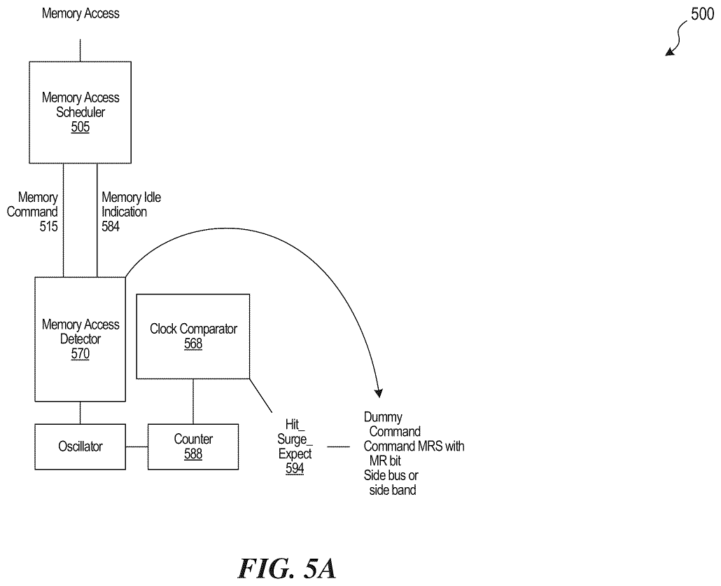

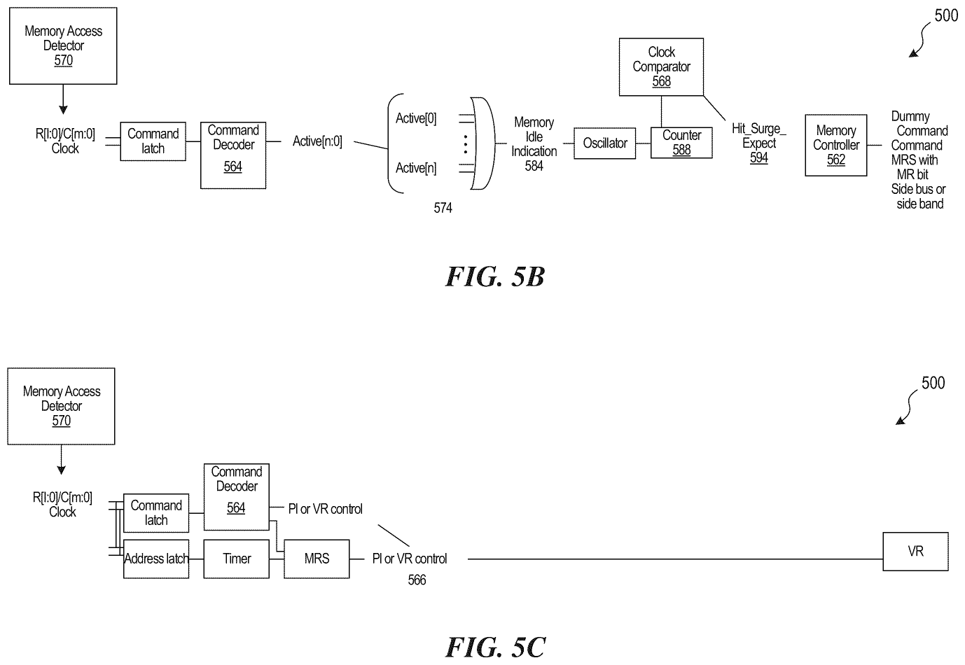

FIG. 5A illustrates a surging current detector 500 as part of a memory controller, in accordance with embodiments of the present technology. The surging current detector 500 can detect the likelihood of a surging current based on, for example, a likelihood of memory activity after a long idle period (e.g., an idle period exceeding a threshold number of cycles). When the surging current detector 500 is in the memory controller, it can use a memory access scheduler 505 to detect if any memory accesses are scheduled and to generate a Memory Idle Indication 584 and/or a Memory Command 515 accordingly (e.g., in advance). In some embodiments, the memory access scheduler 505 is the controller's interface to the host. The Memory Idle Indication 584 can control incrementing a counter 588 at each clock cycle (e.g., determined by a Clock Comparator 568) to generate a Hit_Surge_Expect 594. The Hit_Surge_Expect 594 can be a signal sent to a Memory Controller 562 to prepare the system for a surge in current (e.g., by a Dummy Command, a Command MRS with MR bit, sent over a Side bus or a side band). Additionally, or alternatively, a Memory Access Detector 570 can receive the Memory Idle Indication 584 and/or the Memory Command 515 and directly prepare the system for a surge in current (e.g., by a Dummy Command, a Command MRS with MR bit, sent over a Side bus or a side band).

FIGS. 5B and 5C illustrate a surging current detector 500 as part of a memory device, in accordance with embodiments of the present technology. FIGS. 5B and 5C illustrate the surging current detector 500 receiving commands from a Memory Access Detector 570 (e.g., the controller) to determine active versus idle. FIG. 5B illustrates an example embodiment in which a Command Decoder 564 receives the commands and translates them to an OR gate 574 that can generate a Memory Idle Indication 584. The Memory Idle Indication 584 can control incrementing a counter 588 at each clock cycle (e.g., determined by a Clock Comparator 568) to generate a Hit_Surge_Expect 594 (e.g., a signal sent to a Memory Controller 562 to prepare the system for a surge in current). Rather than preparing the system for a surge in current by a Hit_Surge_Expect 594, FIG. 5C illustrates the Command Decoder receiving commands and sending them to PI or VR control 566 to directly control the VR.

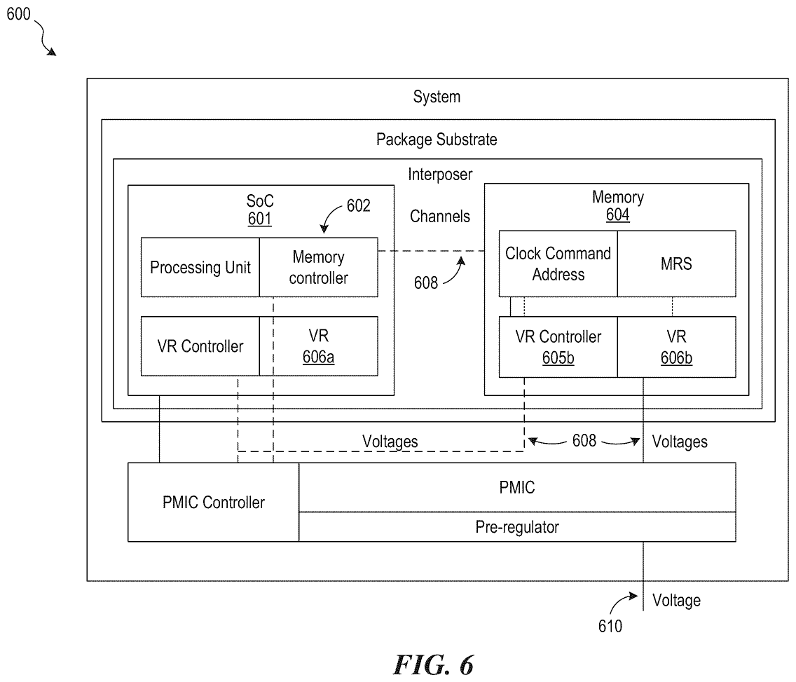

FIG. 6 illustrates a system 600 configured to attenuate supply voltage fluctuations, in accordance with embodiments of the present technology. As illustrated in FIG. 6, the system includes a host system-on-chip (SoC) 601 and memory device 604. In the embodiment of the system 600 illustrated in FIG. 6, the SoC 601 and memory device 604 are placed on an interposer (e.g., a silicon interposer), though it will be appreciated that in other embodiments, the SoC and memory device may be packaged differently. The SoC 601 includes a memory controller 602, which interfaces with the memory device 604. In some embodiments of the system 600, the memory controller 602 includes a voltage-threshold violation detection circuit (for example, the voltage-threshold violation detection circuit 312 illustrated in FIG. 3). As described herein, the voltage-threshold violation detection circuit is configured to detect the potential for excessive fluctuations on a supply voltage 610 and generate a control signal based on which the supply voltage fluctuation can be attenuated. Although FIG. 6 illustrates an embodiment of the system 600 in which the voltage-threshold violation detection circuit is part of the memory controller 602, it will be appreciated that in other embodiments of the system, the voltage-threshold violation detection circuit may be part of the memory device 604.

As described herein, fluctuations may occur on the supply voltage 610 for one or more reasons. For example, the supply voltage 610 may fluctuate due to an inrush of current (e.g., due to an initialization state) and/or a surge of current (e.g., due to a switch to a busy state after staying in a long-term idle state). In some embodiments, the voltage-threshold violation detection circuit can detect an inrushing current based on a Power Up signal and/or a Reset signal received from a host (e.g., the SoC 601). In some embodiments, the voltage-threshold violation detection circuit can detect a surge of current based on counting a number of idle clock cycles.

The system 600 can include one or more VRs. For example, as illustrated in FIG. 6, the SoC 601 can include a voltage regulator 606a, and the memory device 604 can include a voltage regulator 606b. The voltage regulators 606a and 606b can be configured to maintain an optimal PI state for the system 600. The system 600 can also include a channel 608 through which the memory controller 602 and memory device 604 are coupled.

Although FIG. 6 illustrates an embodiment of the system 600 with one channel 608 coupling the memory controller 602 and memory device 604, it will be appreciated that multiple channels may couple the memory controller and memory device. For example, the one or more channels 608 can include a memory channel (e.g., comprising a command/address bus and data bus) and/or side-band channel that operates independently of the memory channel. The memory controller 602 and/or voltage-threshold violation detection circuit can be configured to transmit a control signal, indicating a detected occurrence of an inrushing current or surging current, to the memory device over the one or more channels 608. For example, the memory controller 602 can transmit a Dummy Command and/or an MRS command to the memory device 604 over a command/address bus. As a further example, the memory controller 602 can transmit a signal (e.g., an indication of an expected inrushing current and/or expected surge current) over an 12C or IEEE1500 side-band channel.

In some embodiments, the memory channel includes signals (e.g., CLK, CA, DQS, or DQ). In some embodiments, a signal combination included in the memory channel has not been set to another function, this and can be used as a Dummy Command. In some embodiments, the memory channel is a case of using the side band. The memory controller can use the side band to set and issue a WIR (IEEE1500 command) to the memory device while the memory device is operating so the WIR can function like a dummy command.

In some embodiments, the control signal causes a temporary increase in a response speed and/or a driving ability of one or more of the VRs of the system 600. For example, the memory device 604 can include a VR controller 605b, associated with the voltage regulator 606b, that adjusts operation of the voltage regulator in response to receiving the control signal over the channel 608. In some embodiments, the control signal causes the memory device 604 to consume an initial amount of current. For example, the control signal may be a command that activates a current consuming circuit (not shown) of the memory device 604. It will be appreciated that the memory device 604 and/or current consuming circuit can be configured to consume an initial amount of current that causes a supply voltage fluctuation prior to memory access, allowing the memory device 604 to reach voltage equilibrium before operational defects can occur. It will be appreciated that when the memory device 604 reaches voltage equilibrium, the amount of current consumed by the memory device matches an amount of current that is supplied (e.g., by the PMIC) to within an acceptable tolerance. The acceptable tolerance defines a min-max threshold, outside of which memory operation defects can occur.

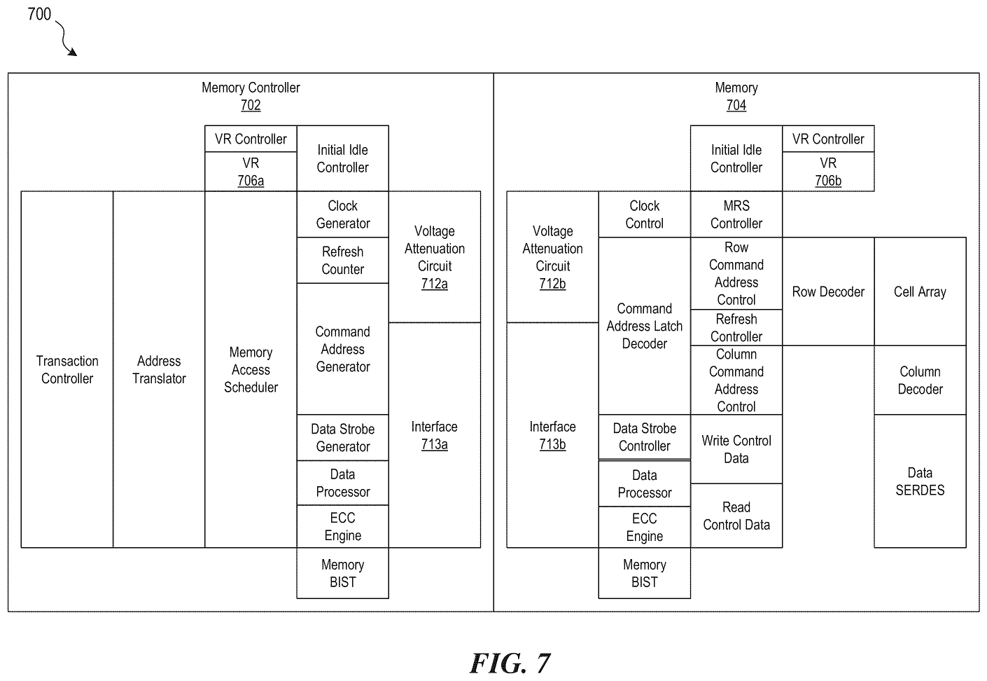

FIG. 7 illustrates a memory system 700 configured to attenuate supply voltage fluctuations, in accordance with embodiments of the present technology. As illustrated in FIG. 7, the memory system 700 includes a memory device 704 and a memory controller 702. It will be appreciated, however, that in some embodiments, the memory system 700 includes a memory device 704 but not a memory controller 702. In some embodiments, the memory system 700 can also include a PMIC, VRs 706a and 706b, a PDN, or any combination of the foregoing components. In these embodiments, methods to attenuate excessive supply voltage fluctuation include detecting a supply voltage fluctuation at a Voltage Attenuation Circuit 712b in the memory device 704 or at a Voltage Attenuation Circuit 712a in the memory controller 702. As illustrated, the memory system 700 can include an interface circuit 713a and 713b in the memory device 704 or in the memory controller 702. In some embodiments, the Voltage Attenuation Circuits 712a and 712b can be further configured to detect surging current from a switch to a busy state after staying in a long-term idle state by measuring idle time following a most recent surge in current, and/or the Voltage Attenuation Circuits 712a and 712b can be further configured to detect inrushing current caused by a Power Up or a Reset signal.

As described herein, the supply voltage (e.g., to the memory device 704) could fluctuate as a result of an inrushing current from an initialization state or a surge of current from a switch to a busy state after staying in a long-term idle state. Accordingly, the Voltage Attenuation Circuits 712a and/or 712b can detect the supply voltage fluctuations (or the likelihood of one occurring). In response to detecting the supply voltage fluctuation, the interface circuit 713a and/or interface circuit 713b generates a control signal. The control signal can, for example, cause the memory device 704 to consume an initial amount of current, and/or the control signal can cause changes to a PMIC, to VRs 706a and 706b, and/or to a PDN.

In some embodiments, the memory system 700 can be further configured to adjust a voltage training to minimize the effect of supply voltage fluctuations. The interface circuit 713a and/or interface circuit 713b can be further configured to adjust the voltage training to minimize the effect of supply voltage fluctuations. In such embodiments, supply voltage fluctuations are used to determine values that are insensitive to such fluctuations for training cycles and a timing of the interface circuits 713a and/or 713b. This time is low-frequency power noise ranging from a few microseconds to several milliseconds. In the very early section of this time, min and max for the amplitude of the voltage are generated, thereby preventing defects from occurring in the operation of the memory device interface.

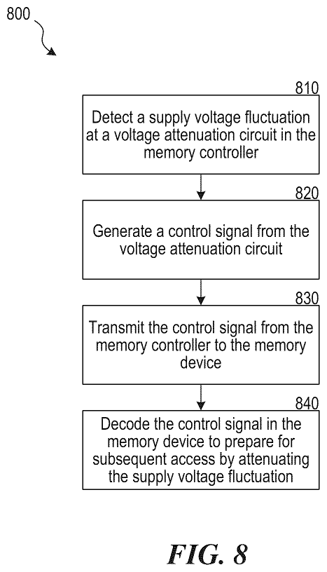

FIG. 8 illustrates a flowchart illustrating a method 800 of attenuating excessive supply voltage fluctuations in a memory subsystem comprising a memory controller and a memory device configured to store and retrieve data. The method 800 includes detecting a supply voltage fluctuation at a voltage-threshold violation detection circuit in the memory controller. The supply voltage fluctuation corresponds to an inrushing current from an initialization state or a surge of current from a switch to a busy state after staying in a long-term idle state (box 810). The method 800 further includes generating a control signal from the voltage-threshold violation detection circuit in response to detecting the supply voltage fluctuation (box 820). The method 800 further includes transmitting the control signal from the memory controller to the memory device (box 830). The method 800 further includes decoding the control signal in the memory device to prepare for subsequent access by attenuating the supply voltage fluctuation (box 840). Although FIG. 8 illustrates an embodiment of the method 800 in which supply voltage fluctuations are detected at a voltage-threshold violation detection circuit in a memory controller, it will be appreciated that in some embodiments of the method 800, the supply voltage fluctuations may be detected at a voltage-threshold violation detection circuit in the memory device itself.

In accordance with one aspect of the present disclosure, the memory devices illustrated in FIGS. 6-7 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.) or a mix of logic and memory dies (e.g., a memory controller die and a memory die controlled thereby).

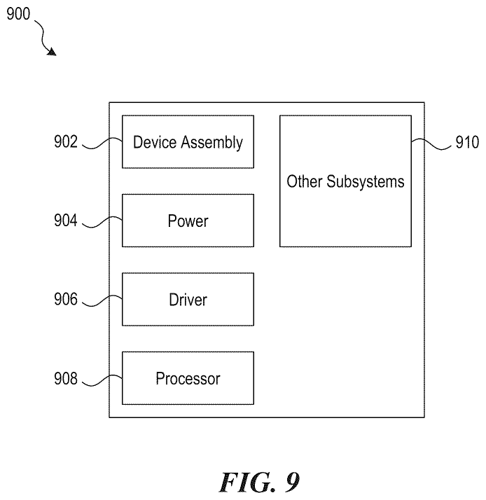

Any one of the memory subsystems and memory devices described above with reference to FIGS. 6-7 can be incorporated into any of a myriad of larger and/or more complex systems, a representative example of which is system 900 shown schematically in FIG. 9. The system 900 can include a semiconductor device assembly (e.g., or a discrete semiconductor device) 902, a power source 904, a driver 906, a processor 908, and/or other subsystems or components 910. The semiconductor device assembly 902 can include features generally similar to those of the semiconductor devices described above with reference to FIGS. 3-4. The resulting system 900 can perform any of a wide variety of functions, such as memory storage, data processing, and/or other suitable functions. Accordingly, representative systems 900 can include, without limitation, handheld devices (e.g., mobile phones, tablets, digital readers, and digital audio players), computers, vehicles, appliances, and other products. Components of the system 900 may be housed in a single unit or distributed over multiple, interconnected units (e.g., through a communications network). The components of the system 900 can also include remote devices and any of a wide variety of computer readable media.

Although in the foregoing example embodiment memory systems have been illustrated and described as including a single memory device, in other embodiments, memory systems can be provided with additional memory devices. For example, the single memory devices illustrated in FIGS. 3 and/or 4 could be replaced with, e.g., a vertical stack of semiconductor devices, a plurality of semiconductor devices, mutatis mutandis.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, may be controlled through doping using various chemical species including, but not limited to, phosphorous, boron, or arsenic. Doping may be performed during the initial formation or growth of the substrate, by ion implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods, in addition to those specific embodiments disclosed herein, may be within the scope of the present technology.

What is claimed is:

1. A method to attenuate excessive supply voltage fluctuations in a memory system comprising a memory controller and a memory device configured to store and retrieve data, the method comprising:
detecting a potential supply voltage fluctuation at a voltage-threshold violation detection circuit in the memory controller, wherein the potential supply voltage fluctuation corresponds to an inrushing current from an initialization state or a surge of current from a switch to a busy state after staying in a long-term idle state;
in response to detecting the potential supply voltage fluctuation, generating a control signal from the voltage-threshold violation detection circuit;
transmitting the control signal from the memory controller to the memory device;
decoding the control signal in the memory device; and
attenuating the potential supply voltage fluctuation to prepare for memory access.

2. The method of claim 1, wherein the inrushing current is detected by receiving a Power Up signal or a Reset signal from an external processor.

3. The method of claim 1, wherein the surge of current is detected by measuring idle time following a most recent surge in current.

4. The method of claim 1, wherein the control signal is transmitted to the memory device over a channel, and wherein the channel can include a memory channel or a side-band channel independent of the memory channel.

5. The method of claim 1, wherein the control signal can include a Dummy Command or a Mode Register Set (MRS) command.

6. The method of claim 1, wherein the control signal comprises a command to consume an initial amount of current in the memory device, and wherein the initial amount of current is configured to cause the supply voltage fluctuation to lapse prior to the memory device being accessed.

7. The method of claim 1, wherein the memory system further comprises a Power Management Integrated Circuit (PMIC), Voltage Regulators (VRs), and a Power Delivery Network (PDN), and wherein the control signal comprises changes to the PMIC, the VRs, or to the PDN.

8. The method of claim 7, wherein the changes include temporarily increasing response speed and driving ability of the VRs.

9. The method of claim 1, wherein the method further comprises adjusting voltage training to attenuate supply voltage fluctuations, and wherein supply voltage fluctuations are used to determine values insensitive to such fluctuations for training cycles and timing of the voltage-threshold violation detection circuit.

10. The method of claim 3, wherein measuring idle time following a most recent surge in current includes counting a number of clock cycles during which the memory device is idle, and wherein generating the control signal further comprises:
determining if the number of idle clock cycles prior to the supply voltage fluctuation exceeds a threshold; and
generating the control signal based on the determination.

11. A memory system configured to attenuate supply voltage fluctuations, the memory system comprising:
a memory controller, including:
a voltage-threshold violation detection circuit configured to detect a supply voltage fluctuation and generate a control signal to attenuate the supply voltage fluctuation;
a memory device configured to store and retrieve data, including:
voltage regulators configured to maintain an optimal Power Integrity (PI) state; and
a channel coupling the memory controller and the memory device, wherein the channel is configured to transmit the control signal from the memory controller to the memory device.

12. The memory system of claim 11, wherein the supply voltage fluctuation corresponds to an inrushing current from an initialization state or a surge of current from a switch to a busy state after staying in a long-term idle state.

13. The memory system of claim 12, wherein the inrushing current from an initialization state is detected by receiving a Power Up signal or a Reset signal from an external processor.

14. The memory system of claim 12, wherein the surge of current from a switch to a busy state after staying in a long-term idle state is detected by counting a number of idle clock cycles following a most recent surge in current.

15. The memory system of claim 11, wherein the system further comprises Voltage Regulators (VRs), and wherein the control signal comprises temporarily increasing response speed and driving ability of the VRs.

16. The memory system of claim 11, wherein the control signal comprises a command to consume an initial amount of current in the memory device, and wherein the initial amount of current is configured to cause supply voltage fluctuations to lapse prior to the memory device actually being accessed.

17. The memory system of claim 12, wherein the channel comprises a memory channel or a side-band channel independent of a memory channel, and wherein the control signal comprises a Dummy Command or a Mode Register Set (MRS) command.

18. The memory system of claim 11, wherein the voltage-threshold violation detection circuit is further configured to detect surging current from a switch to a busy state after staying in a long-term idle state by measuring idle time following a most recent surge in current.

19. The memory system of claim 11, wherein the voltage-threshold violation detection circuit is further configured to adjust voltage training to attenuate supply voltage fluctuations, and wherein supply voltage fluctuations are used to determine values insensitive to such fluctuations for training cycles and timing of the voltage-threshold violation detection circuit.

20. A method to attenuate excessive supply voltage fluctuations in a memory subsystem comprising a memory device configured to store and retrieve data, as well as a Power Management Integrated Circuit (PMIC), Voltage Regulators (VRs), and a Power Delivery Network (PDN), the method comprising:
detecting a supply voltage fluctuation at a voltage-threshold violation detection circuit in the memory device, wherein the supply voltage fluctuation is resulting from an inrushing current from an initialization state or a surge of current from a switch to a busy state after staying in a long-term idle state; and
in response to detecting the supply voltage fluctuation, generating a control signal from an interface circuit in the memory device, wherein the control signal comprises consuming an initial amount of current, or it comprises changes to a PMIC, to VRs, and to a PDN.
